(19) United States
(12) Patent Application Publication
(10) Pub. No.: US 2026/0206611 A1
(43) Pub. Date: Jul. 16, 2026

(54) METHOD FOR FABRICATING GLASS INTERPOSER WITH THROUGH GLASS VIA

(71) Applicant: E&R ENGINEERING CORPORATION, KAOHSIUNG CITY (TW)

(72) Inventor: SCHANG-JING HON, KAOHSIUNG CITY (TW)

(21) Appl. No.: 19/018,119

(22) Filed: Jan. 13, 2025

(30) Foreign Application Priority Data
Jan. 13, 2025 (TW) 114101235

(51) Int. Cl. H01L 21/48; C03C 15/00; C03C 17/09; C03C 17/10; C03C 23/00; C25D 5/54; C25D 7/12

(52) U.S. Cl. CPC H10W 70/095; C03C 15/00; C03C 17/09; C03C 17/10; C03C 23/0025; C25D 5/54; C25D 7/123; C03C 2218/115; C03C 2218/154; C03C 2218/31

(57) ABSTRACT

A method for fabricating a glass interposer with a through glass via (TGV) has steps of: attaching a first carrier onto a second surface of a glass substrate, forming a through hole in the glass substrate, forming a seed layer on an inner sidewall of the through hole and on a first surface of the glass substrate; attaching a second carrier onto the first surface of the glass substrate and removing the first carrier from the glass substrate; applying an electroplating voltage to the seed layer of the glass substrate to electroplate the through hole by depositing a metallic material in the through hole as a conductive pillar; and removing the second carrier. By the method, the glass interposer does not need to be further thinned, and the conductive pillar formed in the glass substrate completely fills the through hole.

### CROSS REFERENCE TO RELATED APPLICATIONS

This non-provisional application claims the benefit under 35 U.S.C. § 119(a) to Patent Application No. 114101235 filed in Taiwan on Jan. 13, 2025, which is hereby expressly incorporated by reference into the present application.

### BACKGROUND OF THE INVENTION

### 1. Field of the Invention

The present invention relates to an interconnection for electrically connecting between two electronic elements, and more particularly to a method for fabricating a glass interposer with through glass vias (TGV).

### 2. Description of the Related Art

A through silicon via (TSV) is a vertical electrical interconnection structure formed through a silicon substrate and widely applied in semiconductor packaging processes, for example, to vertically and electrically interconnect multiple stacked chips.

FIGS. 10 to 13 are schematic views of TSV fabricating processes. With reference to FIG. 10, a blind hole 91 is formed on a top surface of a silicon substrate 90 and extends inward the silicon substrate 90 to a certain depth. With reference to FIG. 11, a seed layer 92 is formed on an inner sidewall of the blind hole 91 and on the top surface of the silicon substrate 90 for facilitating subsequent electroplating processes. Following the seed layer 92, a conductive layer 93 made of copper is electroplated on the seed layer 92 and in the blind hole 91 as shown in FIG. 12, wherein the conductive layer 93 on the top surface of the silicon substrate 90 may be configured as a circuit layer.

With reference to FIG. 13, after forming the conductive layer 93 on the silicon substrate 90, the silicon substrate 90 has to be thinned by grinding its bottom surface to reduce the thickness to the extent that the conductive layer 93 in the blind hole 91 is exposed. The blind hole 91 filled with the conductive layer 93 is known as the through silicon via (TSV).

The finished product as shown in FIG. 13 is a silicon-based interposer in which the TSV formed in the silicon substrate 90 functions as an interconnection to connect elements at opposite sides of the interposer electrically. However, the foregoing fabricating processes for the TSV may be confronted with some technical problems as follows.
1. The through silicon via with a high aspect ratio (AR) may be a necessary interconnection structure for specific application fields. However, when electroplating the seed layer 92 and the conductive layer 93 with a general electroplating process, growing a uniform seed layer 92 in a blind hole 91 with a high aspect ratio is not easy, particularly at the bottom of the blind hole 91. The uneven distribution of the seed layer 92 makes it difficult for the conductive layer 93 to be coated evenly on the inner sidewall of the blind hole 91. Since an electroplating voltage applied to the seed layer 92 is around a top opening of the blind hole 91, metallic material to be deposited will be more likely accumulated near the top opening. A void 94 as shown in FIG. 13 may occur in the blind hole 91 during the electroplating processes, i.e. the metallic material is incapable of filling the blind hole 91. The existence of the void 94 may impair the electrical interconnection quality and stability of the interposer.
2. After the top surface of the silicon substrate 90 has been processed, the bottom surface of the silicon substrate 90 has to be grinded such as by chemical-mechanical polishing (CMP) to remove excess silicon substrate 90 so that the remaining silicon substrate 90 can meet the thickness specifications as required. For example, a silicon substrate 90 with an original thickness of 800 micrometers (μm) may be thinned to be less than 100 μm eventually. Therefore, fabricating the silicon-based interposer is generally time-consuming and costly.

### SUMMARY OF THE INVENTION

An objective of the present disclosure is to provide a method for fabricating a glass interposer with a through glass via (TGV) without needing to further polish the substrate.

The method for fabricating the glass interposer may comprise steps of:
providing a glass substrate having a first surface and a second surface opposite to each other, where a first carrier is attached onto the second surface;
forming a through hole in the glass substrate, the through hole having a first opening defined on the first surface as well as a second opening defined on the second surface;
forming a seed layer on an inner sidewall of the through hole and on the first surface of the glass substrate;
attaching a second carrier onto the first surface of the glass substrate and removing the first carrier from the glass substrate;
applying an electroplating voltage to the seed layer of the glass substrate to electroplate the through hole by depositing a metallic material in the through hole to form a conductive pillar; and
removing the second carrier to expose the first surface of the glass substrate.

Based on the method, a relatively thin glass substrate is used as a raw material to form the through glass via (TGV) without redundant procedures such as grinding the glass substrate, thereby reducing the production cost and time.

Other objectives, advantages and novel features of the invention will become more apparent from the following detailed description when taken in conjunction with the accompanying drawings.

### BRIEF DESCRIPTION OF THE DRAWINGS

FIG. 1 is a flowchart showing the method for fabricating a glass interposer of the present invention;

FIGS. 2 to 9 are schematic views showing fabricating processes of a glass interposer in accordance with the present invention;

FIGS. 10 to 13 are schematic views showing conventional TSV fabricating processes.

### DETAILED DESCRIPTION OF THE INVENTION

Directional terms as used herein, for example, up, down, right, left, front, back, top, bottom are made only with reference to the figures as illustrated and are not intended to imply absolute orientation unless otherwise specified.

According to the invention, a method for fabricating a glass interposer with a through glass via (TGV) is proposed to construct an interconnection structure in a glass substrate. The glass interposer may be applied in semiconductor packaging processes to accomplish a vertical and electrical interconnection between two objects, such as chips, circuits, semiconductor packages, etc.

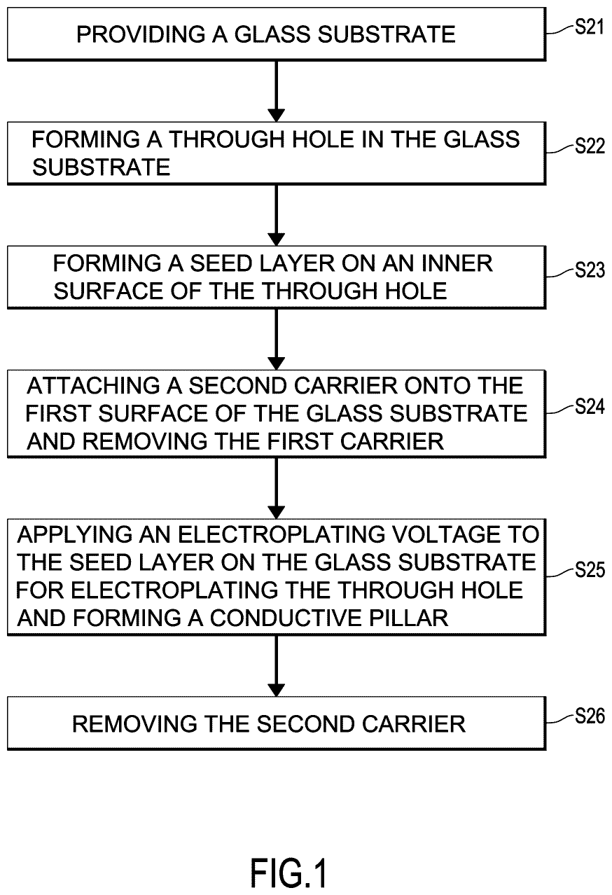

With reference to FIG. 1, the method of the present invention may comprise the following steps S21 to S26.

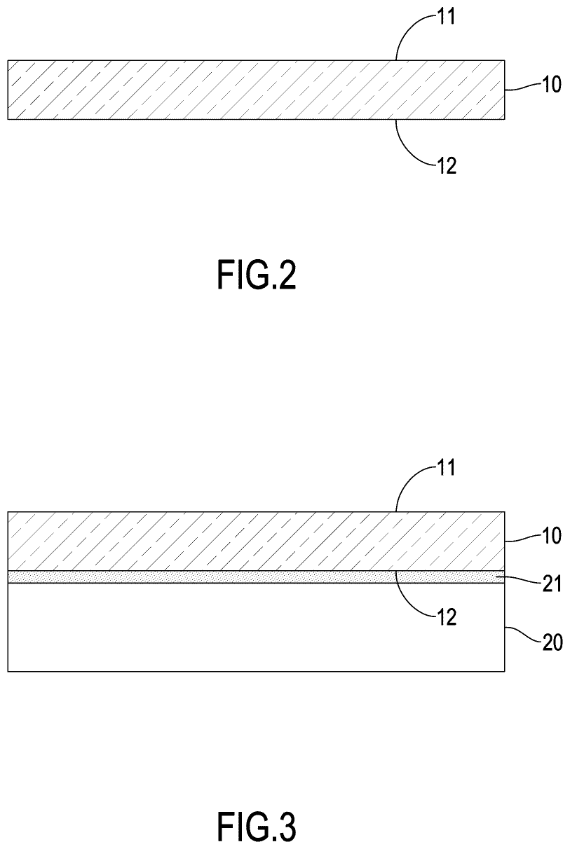

S21: Providing a glass substrate. As shown in FIGS. 2 and 3, a glass substrate 10 with a thickness less than 100 μm has a first surface 11 and a second surface 12 opposite to each other. The first surface 11 and the second surface 12 here are also respectively referred to as a top surface and a bottom surface of the glass substrate 10. A first carrier 20 is attached onto the second surface 12 of the glass substrate 10; for example, the first carrier 20 can be attached to the second surface 12 of the glass substrate 10 through an adhesive layer 21.

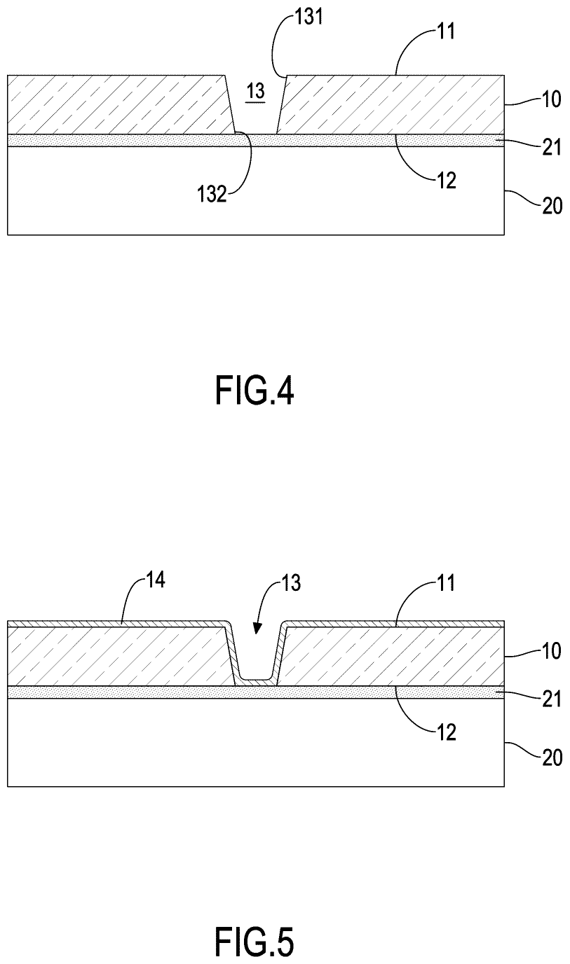

S22: Forming a through hole in the glass substrate. With reference to FIG. 4, by performing a laser modification and etching processes onto the first surface 11 of the glass substrate 10, a through hole 13 extending from the first surface 11 to the second surface 12 will be formed thought the glass substrate 10. The through hole 13 has two opposite openings, which are defined as a first opening 131 formed on the first surface 11 and a second opening 132 formed on the second surface 12. In comparison to the second opening 132, the first opening 131 may have a larger diameter.

S23: Forming a seed layer on an inner surface of the through hole. With reference to FIG. 5, a seed layer 14 will be formed on the inner surface of the through hole 13 by physical vapor deposition (PVD) such as a sputter coating procedure. The seed layer 14 is applied to enhance adhesion between a metal film subsequently sputtered and the glass substrate 10 and to promote the yield of electroplating processes. The material of the seed layer 14 may be selected from nickel (Ni), chromium (Cr), titanium (Ti), titanium alloy (such as titanium copper TiCu), etc. according to demand of the electroplating processes. Aside from being coated on the inner sidewall of the through hole 13, the seed layer 14 is further distributed on the first surface 11 of the glass substrate 10 in this embodiment.

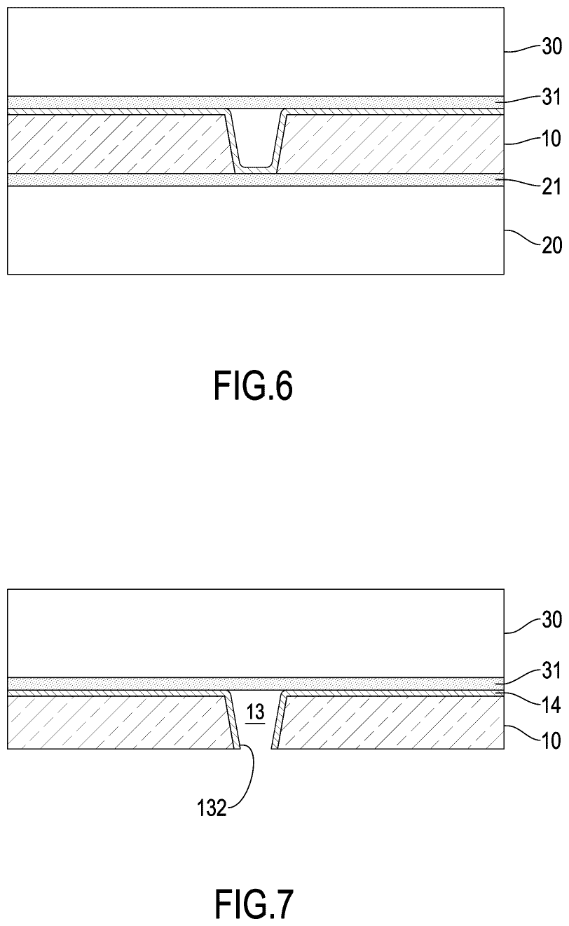

S24: Attaching a second carrier onto the first surface of the glass substrate and exposing the second surface of the glass substrate. With reference to FIG. 6, a second carrier 30 is attached onto the first surface 11 of the glass substrate 10. The second carrier 30 can be attached to the first surface 11 of the glass substrate 10 through another adhesive layer 31.

With reference to FIG. 7, the first carrier 20 will then be removed from the second surface 12 of the glass substrate 10 to expose the second surface 12 and the second opening 132 of the through hole 13. Even the first carrier 20 has been removed, the glass substrate 10 is still supported by the second carrier 30. Laser debonding and plasm descum processes may be used to take the first carrier 20 away from the glass substrate 10, where a laser beam will irradiate onto the first carrier 20 to separate it from the adhesive layer 21 and the plasma will be subsequently applied to remove residual contaminants like the adhesive on the second surface 12.

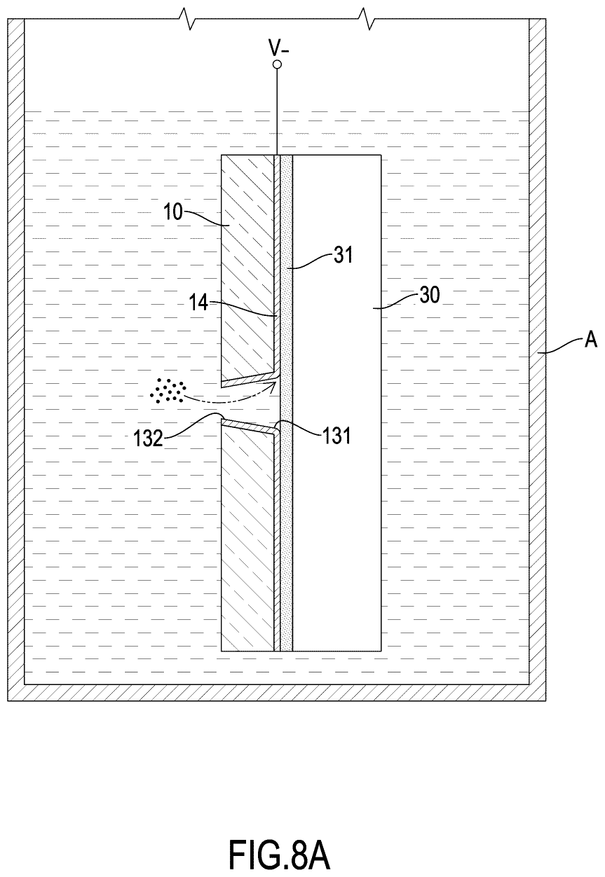

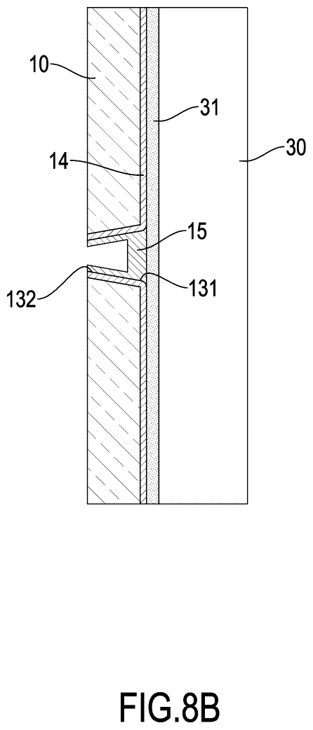

S25: Applying an electroplating voltage to the seed layer on the glass substrate for electroplating the through hole and forming a conductive pillar therein. With reference to FIG. 8A, when performing the electroplating process, the glass substrate 10 will be held lengthwisely in an electroplating tank A. The seed layer 14 is connected electrically to an electroplating electrode (cathode) to receive an electroplating voltage V−. Because the electroplating voltage V− is applied to the seed layer 14 near the first opening 131, relatively inside of the through hole 13 as seen on the drawing while the second opening 132 is close to outside, metal ions(copper ions or other cations) to be deposited will enter into the through hole 13 from the second opening 132 and move toward the first opening 131, and then accumulate from the inner sidewall of the through hole 13 close to the first opening 131. That is to say, the metal ions will enter from the second opening 132 of a small diameter and move to the first opening 131 of a large diameter. With reference to FIG. 8B, the metallic material will be gradually deposited from the first opening 131 toward the second opening 132 to form a conductive pillar 15, and eventually fill the through hole 13.

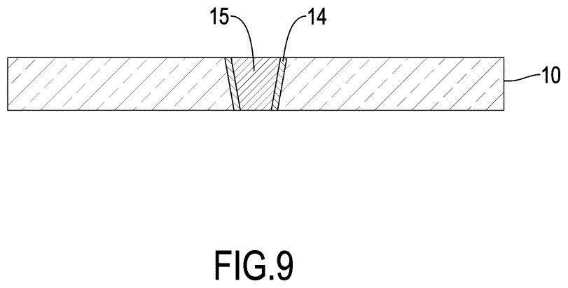

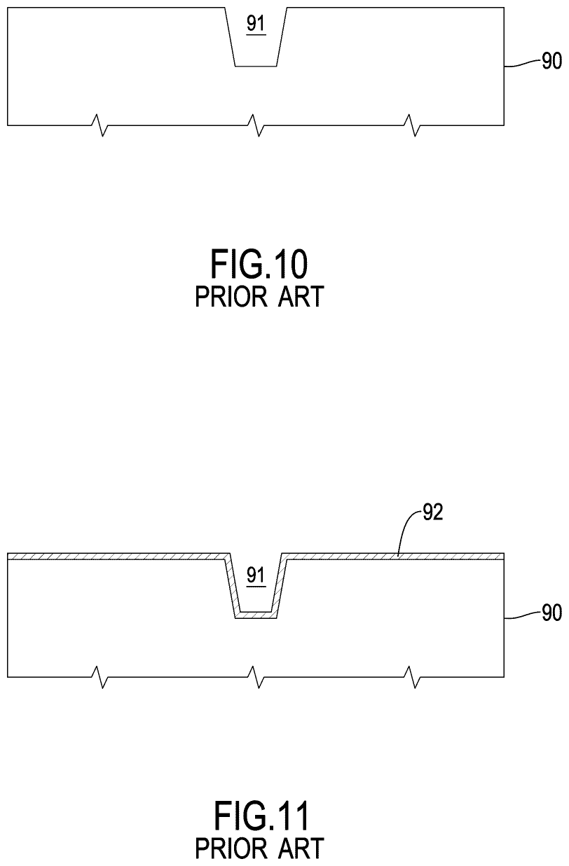

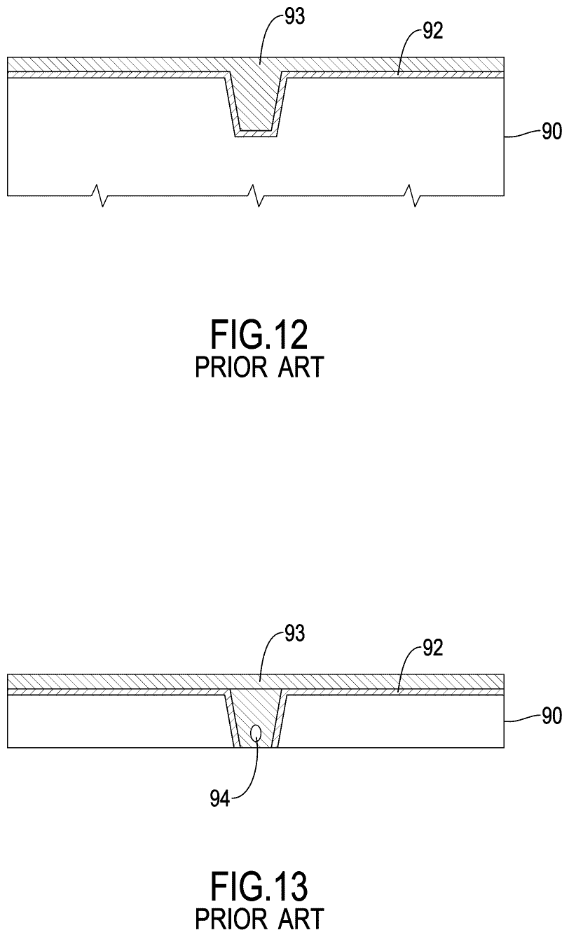

S26: Removing the second carrier to expose the first surface of the glass substrate. With reference to FIG. 9, after finishing the electroplating process, the second carrier 30 will be taken away from the first surface 11 of the glass substrate 10. The removal of the second carrier 30 from the glass substrate 10 may include processes of laser debonding and plasm descum, where a laser beam is irradiated onto the second carrier 30 to separate it from the adhesive layer 31 and then plasma is applied to clean residual contaminants such as the adhesive on the first surface 11.

In the embodiment of the present invention, the seed layer 14 deposited on the first surface 11 of the glass substrate 10 will be further removed.

As shown in FIG. 9, the through hole 13 in the glass substrate 10 is filled with electroplated filler deemed as the conductive pillar 15 with two opposite ends flush with the first surface 11 and the second surface 12 respectively.

The finished product as shown in FIG. 9 is known as the glass interposer having a through glass via (TGV) in which a metallic material is filled, where the through glass via is able to electrically interconnect different objects at opposite sides of the glass substrate.

In short, the method in accordance with the present invention may include features as follows.
1. The glass substrate as the raw material for fabricating the glass interposer has the characteristics of low thermal expansion coefficient (CTE). The glass interposer will be an appropriate alternative to substitute for silicon-based interposer.
2. The thin glass substrate, for example less than 100 μm, may be taken as the base material. Thinning procedure is not necessary for the glass substrate. Accordingly, the step of back grinding applied to the substrate as done by conventional art is avoided, thereby reducing production cost and time.
3. During the electroplating process of the through hole, the electroplating voltage is provided from an inside of the through hole, i.e. the place where the first opening is located, which differs from the prior art that applies the electroplating voltage from the relatively outside of a blind hole. Therefore, the through hole will be filled to avoid occurrence of voids, and the production yield can be improved.

Even though numerous characteristics and advantages of the present invention have been set forth in the foregoing description, together with details of the structure and function of the invention, the disclosure is illustrative only. Changes may be made in detail, especially in matters of shape, size, and arrangement of parts within the principles of the invention to the full extent indicated by the broad general meaning of the terms in which the appended claims are expressed.

What is claimed is:

1. A method for fabricating a glass interposer with a through glass via, the method comprising steps of:
providing a glass substrate having a first surface and a second surface opposite to each other, where a first carrier is attached onto the second surface;
forming a through hole in the glass substrate, the through hole having a first opening defined on the first surface as well as a second opening defined on the second surface;
forming a seed layer on an inner sidewall of the through hole and on the first surface of the glass substrate;
attaching a second carrier onto the first surface of the glass substrate and removing the first carrier from the glass substrate;
applying an electroplating voltage to the seed layer of the glass substrate to electroplate the through hole by depositing a metallic material in the through hole to form a conductive pillar; and
removing the second carrier to expose the first surface of the glass substrate.

2. The method as claimed in claim 1, wherein in the step of providing a glass substrate, the glass substrate has a thickness less than 100 micrometers (μm).

3. The method as claimed in claim 1, wherein in the step of forming a through hole, laser modification and etching processes are performed onto the first surface of the glass substrate to form the through hole extending from the first surface to the second surface; and
the first opening is greater than the second opening in diameter.

4. The method as claimed in claim 1, wherein in the step of forming a seed layer, the seed layer is formed by depositing a metallic material through physical vapor deposition (PVD).

5. The method as claimed in claim 1, wherein in the step of electroplating the through hole by depositing a metallic material, the metallic material fills completely the through hole to form the conductive pillar having two opposite ends flush with the first surface and the second surface respectively.

6. The method as claimed in claim 1, wherein the first carrier is attached onto the second surface of the glass substrate by an adhesive layer; the second carrier is attached onto the first surface of the glass substrate by another adhesive layer.

7. The method as claimed in claim 6, wherein in the step of removing the first carrier, a laser beam is irradiated to the first carrier to separate the first carrier and the adhesive layer, and then plasma is applied to clean the second surface of the substrate.

8. The method as claimed in claim 7, wherein in the step of removing the second carrier, a laser beam is irradiated to the second carrier to separate the first carrier and the adhesive layer, and then plasma is applied to clean the first surface of the substrate.

9. The method as claimed in claim 7, wherein after the second carrier has been removed, the seed layer on the first surface is then cleaned from the glass substrate.
